(19) United States
(12) Patent Application Publication
(10) Pub. No.: US 2025/0126852 A1
(43) Pub. Date: Apr. 17, 2025

(54) SEMICONDUCTOR DEVICE

(71) Applicant: FUJI ELECTRIC CO., LTD., Kawasaki-shi (JP)

(72) Inventor: Noriaki YAO, Matsumoto-city (JP)

(73) Assignee: FUJI ELECTRIC CO., LTD., Kawasaki-shi (JP)

(21) Appl. No.: 18/818,376

(22) Filed: Aug. 28, 2024

(30) Foreign Application Priority Data
Oct. 11, 2023 (JP) 2023-176148

(51) Int. Cl. H01L 29/06; H01L 29/78

(52) U.S. Cl. CPC H10D 62/108; H10D 30/665; H10D 62/126

(57) ABSTRACT

The semiconductor substrate has an active region, a termination regions surrounding a periphery of the active region, and a transition region between the active region and the termination region. The transition region has a portion that overlaps an outer peripheral portion of the active region by a predetermined width. The portion of the transition region includes at least one pair of one of the n-type column regions in the active region and an adjacent one of the p-type column regions in the active region. The parallel pn layer exhibits doping concentration distributions of n-type and p-type in each of which the doping concentration is relatively high in a center portion of the active region, progressively decreases in the transition region in a direction from the active region to the edge termination region, and is relatively high in the termination region.

### CROSS REFERENCE TO RELATED APPLICATIONS

This application is based upon and claims the benefit of priority of the prior Japanese Patent Application No. 2023-176148, filed on Oct. 11, 2023, the entire contents of which are incorporated herein by reference.

### BACKGROUND OF THE INVENTION

### 1. Field of the Invention

Embodiments of the invention relate to a semiconductor device.

### 2. Description of the Related Art

In a conventional vertical semiconductor device, a drift layer has a super junction (SJ) structure that is configured by n-type column regions and p-type column regions, thereby reducing on-resistance. Further, to ensure a predetermined breakdown voltage in an edge termination region, a SJ structure is further formed in the edge termination region under conditions different from conditions of an active region. A device has been disclosed in which, to make the breakdown voltage of the edge termination region higher than a breakdown voltage of the active region, a doping concentration of the column regions configuring the SJ structure is relatively lower in the edge termination region (for example, refer to Japanese Patent No. 5342752, Japanese Laid-Open Patent Publication No. 2007-266505, Japanese Laid-Open Patent Publication No. 2015-220367, and Japanese Laid-Open Patent Publication No. 2023-505942).

### SUMMARY OF THE INVENTION

According to an embodiment of the present embodiment, a semiconductor device includes: a semiconductor substrate having a first main surface and a second main surface opposite to each other, the semiconductor substrate further having an active region; a termination region disposed outside the active region, surrounding a periphery of the active region in a plan view of the semiconductor device; and a transition region between the active region and the termination region; a parallel pn layer in which a plurality of first-conductivity-type regions and a plurality of second-conductivity-type regions are disposed adjacent to and repeatedly alternating with one another in a direction parallel to the first main surface of the semiconductor substrate, the parallel pn layer being provided in the semiconductor substrate, in the active region, the transition region, and the termination region; a device structure provided in the active region, between the first main surface of the semiconductor substrate and the parallel pn layer; a first electrode provided at the first main surface of the semiconductor substrate and electrically connected to the device structure; and a second electrode provided at the second main surface of the semiconductor substrate. The transition region overlaps an outer peripheral portion of the active region, and includes at least one adjacent pair of conductivity-type regions that includes one of the plurality of first-conductivity-type regions and one of the plurality of second-conductivity-type regions, which are adjacent to each other in the active region. The parallel pn layer exhibits: a first-conductivity-type doping concentration distribution in which a first-conductivity-type doping concentration is relatively high in a center portion of the active region, the center portion being farther from a semiconductor substrate end than is the transition region in said direction parallel to the first main surface of the semiconductor substrate, the first-conductivity-type doping concentration progressively decreases in the transition region in a direction from the active region to the termination region, and the first-conductivity-type doping concentration is relatively low in the termination region; and second-conductivity-type doping concentration distribution in which a second-conductivity-type doping concentration is relatively high in the center portion of the active region, the second-conductivity-type doping concentration progressively decreases in the transition region in the direction from the active region to the termination region, and the second-conductivity-type doping concentration is relatively low in the termination region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to an embodiment is viewed from a front side of a semiconductor substrate thereof.

FIG. 2 is a cross-sectional view along cutting line A-A′ in FIG. 1.

FIG. 3A is a plan view depicting an example of a state of the semiconductor device according to the embodiment during manufacture.

FIG. 3B is a plan view depicting an example of a state of the semiconductor device according to the embodiment during manufacture.

FIG. 4 is a cross-sectional view of a structure along cutting line B-B′ in FIGS. 3A and 3B.

FIG. 5 is a characteristics diagram showing results of simulation of electric field strength during reverse recover of body diodes of an example and a reference example.

FIG. 6 is a diagram schematically depicting a state during reverse recovery of a body diode of the semiconductor device according to the embodiment.

FIG. 7 is a diagram depicting a cross-sectional view of a structure of a semiconductor device according to the reference example and a state during reverse recovery of a body diode thereof.

FIG. 8 is a plan view depicting a state of the semiconductor device according to the reference example during manufacture.

FIG. 9 is a cross-sectional view depicting the structure along cutting line AA-AA′ in FIG. 8.

FIG. 10A is a plan view depicting another example of a layout when the semiconductor device according to the embodiment is viewed from the front side of the semiconductor substrate thereof.

FIG. 10B is a plan view depicting another example of a layout when the semiconductor device according to the embodiment is viewed from the front side of the semiconductor substrate.

### DETAILED DESCRIPTION OF THE INVENTION

First, problems associated with the convention techniques are discussed. In a conventional vertical semiconductor device having a SJ structure, a difference in the doping concentrations of column regions of the same conductivity type configuring the SJ structures is large between the active region and the edge termination region, whereby at a boundary between the active region and the edge termination region, the charge of any one of n-type column regions and the charge of an adjacent one of the p-type column regions tends to become unbalanced. Thus, when there is bias in the amount of charge in the column regions due to process variation, local concentration of electric field occurs at the boundary between the active region and the edge termination region, and characteristics degrade such as a decrease in the breakdown voltage.

Here, unbalanced charge means a difference of an amount of charge expressed by a product obtained by multiplying a carrier concentration (concentration of activated dopants) of the n-type column regions and a width of the n-type column regions and an amount of charge expressed by a product obtained by multiplying a carrier concentration of the p-type column regions and a width of the p-type column regions is large and the amount of charge of one of the n-type column regions and the amount of charge of an adjacent one of the p-type column regions are not in equilibrium with each other.

Embodiments of a semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

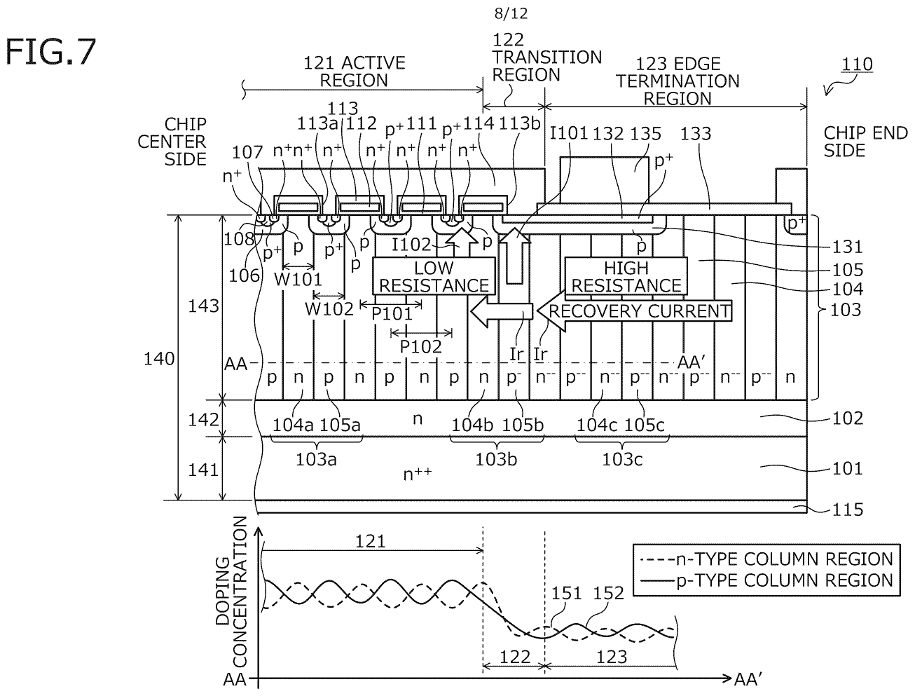

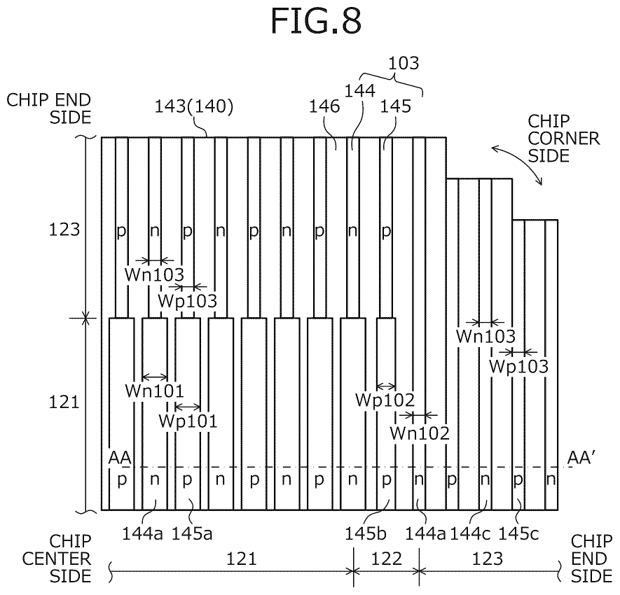

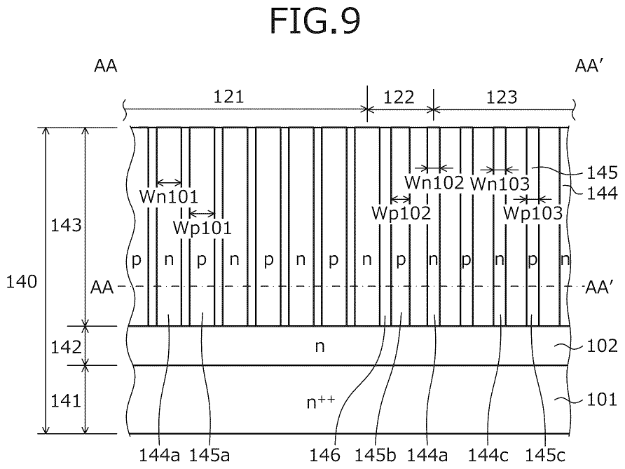

First, a semiconductor device of a reference example and problems associated with the semiconductor device according to the reference example are discussed. FIG. 7 is a diagram depicting a cross-sectional view of a structure of the semiconductor device according to the reference example and a state during reverse recovery of a body diode thereof. FIG. 7 schematically depicts corresponding to the cross-section of a semiconductor device 110, doping concentration distributions 151, 152 in a first direction X, estimated from a method of formation (multistage epitaxial method) for one stage of a parallel pn layer 103 after thermal diffusion treatment. FIG. 8 is a plan view depicting a state of the semiconductor device according to the reference example during manufacture. FIG. 9 is a cross-sectional view depicting the structure along cutting line AA-AA′ in FIG. 8. FIGS. 8 and 9 depict states of the parallel pn layer 103 before the thermal diffusion treatment.

The semiconductor device 110 according to the reference example depicted in FIG. 7 is a planar gate type SJ-metal oxide semiconductor field effect transistor (SJ-MOSFET) having an insulated gate with a metal-oxide-semiconductor three-layer structure and a SJ structure in which the drift layer is the parallel pn layer 103 spanning from an active region 121 of a semiconductor substrate (semiconductor chip) 140 containing silicon (Si) as a semiconductor material, partly through a transition region 122, to an edge termination region 123.

The active region 121 has a substantially rectangular shape in a plan view of the device and is disposed in substantially a center of the semiconductor substrate 140. The edge termination region 123 is a region between the active region 121 and a chip end (an end of the semiconductor substrate 140) and surrounds a periphery of the active region 121 in a substantially rectangular shape in a plan view of the device. The edge termination region 123 faces the active region 121 in the later-described first direction X with the transition region 122 intervening therebetween, and is in contact with the active region 121 in a later-described second direction Y. The transition region 122 intervenes between the active region 121 and the edge termination region 123 in the first direction X.

In the semiconductor substrate 140, epitaxial layers 142, 143 constituting an n-type buffer region 102 and the parallel pn layer 103 are sequentially stacked, in the order stated, on an n⁺⁺-type starting substrate 141 constituting an n⁺⁺-type drain region 101. In the active region 121, between a front surface of the semiconductor substrate 140 and the parallel pn layer 103, the p-type base regions 106, n⁺-type source regions 107, and p⁺-type contact regions 108 are provided while on the front surface of the semiconductor substrate 140, gate insulating films 111, gate electrodes 112, an interlayer insulating film 113, and a source electrode 114 are provided.

In the transition region 122, between the front surface of the semiconductor substrate 140 and the parallel pn layer 103, outer peripheral p-type regions 131, 132 extend from the edge termination region 123 while in a contact hole, a source contact between the outer peripheral p-type region 132 and the source electrode 114 is formed. A portion of the front surface of the semiconductor substrate 140 in the edge termination region 123 is covered by an insulating layer 133 while a gate runner 135 is provided on the insulating layer 133 and faces the outer peripheral p-type regions 131, 132 in a depth direction Z. In an entire area of a back surface of the semiconductor substrate 14, a drain electrode 115 is provided.

The parallel pn layer 103 spans the active region 121, the transition region 122, and the edge termination region 123 and is formed by n-type column regions 104 and p-type column regions 105 disposed adjacent to and repeatedly alternating with one another in the first direction X parallel to the front surface of the semiconductor substrate 140. The n-type column regions 104 and the p-type column regions 105 extend linearly in the second direction Y parallel to the front surface of the semiconductor substrate 140 and orthogonal the first direction X, from the active region 121 to the edge termination region 123 and form square-shaped columns extending linearly in the depth direction Z.

All the n-type column regions 104 and the p-type column regions 105 have substantially same widths W101, W102 in a lateral direction (the first direction X), are disposed at substantially same recursive pitches P101, P102, extend linearly in a longitudinal direction (the second direction Y) from the active region 121 to the edge termination region 123, maintaining substantially the same widths W101, W102, and extend linearly in the depth direction Z, maintaining substantially the same widths W101, W102. In other words, the n-type column regions 104 and the p-type column regions 105, in both a plan view and a cross-sectional view, have a same striped pattern.

The n-type column regions 104 and the p-type column regions 105 are formed by ion implantation of a dopant in the non-doped epitaxial layer 143, using a multistage epitaxy technique. The multistage epitaxy technique is a technique in which, an epitaxial layer is formed by epitaxy divided into multiple stages performed until the epitaxial layer has a predetermined thickness and for each stage of the epitaxy, dopant implanted regions of a predetermined conductivity type are selectively formed in the epitaxial layer by photolithography and ion implantation so as to face dopant implanted regions of a same conductivity type therebelow in the depth direction Z.

The parallel pn layer 103 exhibits the n-type doping concentration distribution 151 and the p-type doping concentration distribution 152 in which, in a portion (hereinafter, the first parallel pn layer 103a) of the parallel pn layer 103 in the active region 121, both the column regions 104 and the column regions 105 have relatively high doping concentrations; in the transition region 122, the column regions 104, 105 having lowered doping concentrations are disposed in descending order of doping concentration so that the column regions 104, 105 relatively closer to the chip end in the first direction X have relatively lower doping concentrations; and in a portion (hereinafter, a third parallel pn layer 103c) of the parallel pn layer 103 in the edge termination region 123, both the column regions 104 and the column regions 105 have a relatively low doping concentration.

The n-type doping concentration distribution 151 and the p-type doping concentration distribution 152 are each formed at each stage of the multistage epitaxy of the epitaxial layer 143. The doping concentration distributions of the column regions 104, 105 for each stage of the epitaxial layer 143 exhibit Gaussian distribution with a depth position of the range of the ion implantation as a vertex. Intersection of the n-type doping concentration distribution 151 and the p-type doping concentration distribution 152 is an interface between the n-type column regions 104 and the p-type column regions 105. A difference in doping concentrations between column regions of the same conductivity type in the first and third parallel pn layers 103a, 103c is large.

Ion implantation masks, respectively, for forming the n-type column regions 104 and the p-type column regions 105 have an opening pattern with relatively narrow opening widths in portions where the doping concentration is relatively low. The ion implantation masks are used to ion-implant a dopant of a predetermined conductivity type by a same dose amount at an entire surface of the non-doped epitaxial layer 143. In the n-type column regions 104 and the p-type column regions 105, the effective doping concentrations are relatively lower in portions where the opening widths of the ion implantation masks are relatively narrower.

In particular, in the parallel pn layer 103, the n-type column regions 104a (104) and the p-type column regions 105a (105) of the first parallel pn layer 103a (portion in the active region 121) have substantially the same widths W101, W102 and substantially the same doping concentrations. The n-type column regions 104a and the p-type column regions 105a that are adjacent to one another have roughly balanced charge therebetween. Of the n-type column regions 104 and the p-type column regions 105, the n-type column regions 104a and the p-type column regions 105a have relatively high doping concentrations.

In a portion (hereinafter, a second parallel pn layer 103b) of the parallel pn layer 103 in the transition region 122, n⁻-type column regions 104b (104) and p⁻-type column regions 105b (105) have substantially the same widths W101, W102 and the same doping concentrations. The n⁻-type column regions 104b and the p-type column regions 105b that are adjacent to one another have roughly balanced charge therebetween. The n⁻-type column regions 104b and the p⁻-type column regions 105b, respectively, have doping concentrations lower than the doping concentrations of the n-type column regions 104a and the p-type column regions 105a of the active region 121.

In the third parallel pn layer 103c (portion of the parallel pn layer 103 in the edge termination region 123), n⁻⁻-type column regions 104c (104) and p⁻⁻-type column regions 105c (105) have substantially the same widths W101, W102 and the same doping concentrations. The n⁻⁻-type column regions 104c and the p⁻⁻-type column regions 105c have roughly balanced charge therebetween. The n⁻⁻-type column regions 104c and the p⁻⁻-type column regions 105c, respectively, have doping concentrations lower than the doping concentrations of the n⁻-type column regions 104b and the p⁻-type column regions 105b in the transition region 122.

Here, balanced charge means that an amount of charge expressed by a product obtained by multiplying the carrier concentration (concentration of activated dopant) and the width W101 of the n-type column regions 104 and an amount of charge expressed by a product obtained by multiplying of the carrier concentration and the width W102 of the p-type column regions 105 are substantially the same and the amount of charge of one of the n-type column regions 104 and the amount of charge of an adjacent one of the p-type column regions 105 are in equilibrium with each other. Substantially the same doping concentration (the carrier concentration) and substantially the same width mean, respectively, the same doping concentration and the same width within a range including an allowable error due to process variation.

Here, in forming the parallel pn layer 103 by the multistage epitaxy technique, n-type dopant implanted regions 144 are each formed by photolithography and ion implantation, in a center (in the first direction X) of a corresponding formation region of the n-type column regions 104, in each stage of the epitaxial layer 143. By photolithography and ion implantation, p-type dopant implanted regions 145 are formed in a center (in the first direction X) of each formation region of the p-type column regions 105, in each stage of the epitaxial layer 143. Thereafter, a thermal diffusion treatment for diffusing dopants in the epitaxial layer 143 is performed.

The n-type dopant implanted regions 144 have portions 144a in the active region 121, each having a width Wn101 that is widest, portions 144b in the transition region 122, each having a width Wn102 that is narrower than the width Wn101 of the portions 144a in the active region 121, and portions 144c in the edge termination region 123, each having a width Wn103 that is narrowest. The p-type dopant implanted regions 145 include portions 145a in the active region 121, each having a width Wp101 that is widest, portions 145b in the transition region 122, each having a width Wp102 that is narrower than the width Wp101 of the portions 145a in the active region 121, and portions 145c in the edge termination region 123, each having a width Wp103 that is narrowest.

Each stage of the parallel pn layer 103 (the epitaxial layer 143) before the thermal diffusion treatment is in a state in which the n-type dopant implanted regions 144 and the p-type dopant implanted regions 145 are disposed alternating with one another repeatedly in the first direction X with non-doped regions (regions of the non-doped epitaxial layer 143 free of implanted dopants) 146 intervening therebetween (FIGS. 8 and 9). The n-type dopant implanted regions 144, at portions thereof adjacent to the p-type dopant implanted regions 145, have the widths Wn101, Wn102, Wn103 and a dose amount of an n-type dopant that are substantially a same as the widths Wp101, Wp102, Wp103 and a dose amount of a p-type dopant of the p-type dopant implanted regions 145 adjacent thereto. In FIGS. 8 and 9, in the epitaxial layer 143, portions having an “n” or a “p” are, respectively, the n-type dopant implanted regions 144 and the p-type dopant implanted regions 145 while portions without an “n” or a “p” are the non-doped regions 146.

By the thermal diffusion treatment thereafter, the n-type dopant implanted regions 144 and the p-type dopant implanted regions 145 of each of the stages of the epitaxial layer 143 diffuse into the non-doped regions 146 adjacent thereto and are in equilibrium. The n-type dopant implanted regions 144 of each of the stages of the epitaxial layer 143 are connected to each other in the depth direction Z. The p-type dopant implanted regions 145 of each of the stages of the epitaxial layer 143 are connected to each other in the depth direction Z. As a result, the n-type dopant implanted regions 144 and the p-type dopant implanted regions 145 of each of the stages of the epitaxial layer 143 form the n-type column regions 104 and the p-type column regions 105 each having substantially the same widths W101, W102.

A vertical MOSFET with the SJ structure in which the drift layer is the parallel pn layer 103 like the semiconductor device 110 according to the reference example described above has a smaller on-resistance as compared to a normal vertical MOSFET in which the drift layer is configured by only an n⁻-type region, whereby increased speed and size reductions of the device are possible, thereby enabling use in various applications. Further, MOSFETs and IGBTs are widely used in power converting applications and MOSFETs used for power converting applications are mainly vertical types having a source electrode and a drain electrode on the front surface and the back surface of the semiconductor substrate, respectively.

In a vertical MOSFET, during the off-state, a depletion layer spreads in a vertical direction (direction between the source electrode and the drain electrode) from pn junctions between the base regions and the drift region, and the depletion layer further spreads in the drift region, in a horizontal direction from the active region to the chip end. Thus, design to suppress spreading of the depletion layer in the horizontal direction in the edge termination region is necessary. Device characteristics are mainly determined by characteristics of the active region and therefore, to maximize semiconductor device performance, in general, the breakdown voltage of the edge termination region is designed to be higher than the breakdown voltage of the active region.

The breakdown voltage is determined by depletion layer width and the greater is the depletion layer width, the higher is the breakdown voltage. While the depletion layer width may be increased by reducing the doping concentration of the drift region, when the depletion layer reaches the chip end, punch-through occurs and the breakdown voltage is not sustained. Thus, while it is necessary to stop the depletion layer in the edge termination region, electric field concentrates at locations where the spreading of the depletion layer is suppressed rapidly and avalanche breakdown occurs, leading to destruction of the semiconductor device. On the other hand, gradually stopping the spread of the depletion layer leads to increases in the width of the edge termination region and increased size of the semiconductor device.

Further, the lower is the doping concentration of the drift region, the higher is the on-resistance. Thus, with consideration of the tradeoff relationship between reducing the size of the semiconductor device and enhancing avalanche breakdown tolerance, and the tradeoff relationship between increasing breakdown voltage and reducing on-resistance, spreading of the depletion layer has to be suppressed in a balanced manner in the edge termination region. In the semiconductor device 110 according to the reference example, the parallel pn layer 103 is also disposed in the edge termination region 123 and thus, a depletion layer has to be suppressed from spreading from pn junctions between the p-type column regions 105 and the n-type column regions 104 in the edge termination region 123.

In the semiconductor device 110 according to the reference example, as for a method of making the breakdown voltage of the edge termination region 123 higher than the breakdown voltage of the active region 121, the ion implantation masks for forming the n-type column regions 104 and the p-type column regions 105 may have an opening pattern in which the opening width in the edge termination region 123 is relatively narrower (for example, the opening width in the edge termination region 123 is about ½ times narrower than the opening width in the active region 121), and the doping concentration of the n-type column regions 104 and the p-type column regions 105 may be relatively lower in the edge termination region 123 than the doping concentration in the active region 121.

Further, in the edge termination region 123, electric field is distributed in a fan-like shape with an outer periphery of the source electrode 114 in the active region 121 as a center, and exhibits distribution in which equipotential lines are congested at predetermined intervals in a predetermined direction, from the outer periphery of the source electrode 114 in the active region 121 to the end of the drain electrode 115 (the chip end at the back side of the semiconductor substrate 140). Thus, depletion of the edge termination region 123 is more difficult than depletion of the active region 121 and the doping concentration of the n-type column regions 104 and the p-type column regions 105 is lowered, whereby increased breakdown voltage is facilitated.

However, in the edge termination region 123, when the doping concentration of the n-type column regions 104 and the p-type column regions 105 is relatively low, a steep doping concentration gradient occurs at a boundary between the active region 121 and the edge termination region 123 and/or in the transition region 122, and at this portion, charge between the n-type column regions 104 and the p-type column regions 105 that are adjacent to one another easily becomes unbalanced. Thus, when the amount of charge of the column regions 104, 105 is biased due to process variation, electric field concentrates locally at the boundary between the active region 121 and the edge termination region 123 and/or in the transition region 122, whereby the breakdown voltage decreases.

Herein, unbalanced charge means a difference of an amount of charge expressed by a product obtained by multiplying the carrier concentration (concentration of activated dopants) of the n-type column regions and the width of the n-type column regions and an amount of charge expressed by a product obtained by multiplying the carrier concentration of the p-type column regions and the width of the p-type column regions, is large and the amount of charge of one of the n-type column regions and the amount of charge of an adjacent one of the p-type column regions are not in equilibrium with each other.

Further, the transition region 122, which as a width (width in the first direction X) that is relatively narrow, is disposed between the active region 121 and the edge termination region 123, or the active region 121 and the edge termination region 123 are in contact with each other. The active region 121 has a relatively low resistance as compared to resistances of the transition region 122 and the edge termination region 123 and thus, when a parasitic pn junction diode (body diode) conducts, holes accumulated in the n⁻⁻-type column regions 104c in the edge termination region 123 becomes recovery (reverse recovery) Ir during reverse recovery of the body diode and easily flows into the active region 121.

In the edge termination region 123, when avalanche breakdown occurs and the recovery current Ir increases, and a large current (the recovery current Ir) concentrates not only on a path I101 with high resistance through a source contact of the transition region 122, to the source electrode 114, but also on a path I102 with low resistance, through the p-type base regions 106 in an outer peripheral portion of the active region 121, to the source electrode 114, whereby the semiconductor device 110 may be destroyed. Thus, in the present embodiment, problematic local concentration of electric field and local concentration of current are suppressed.

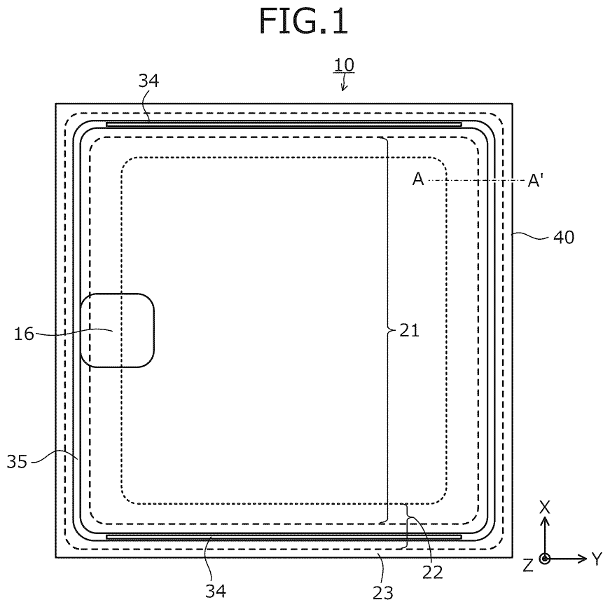

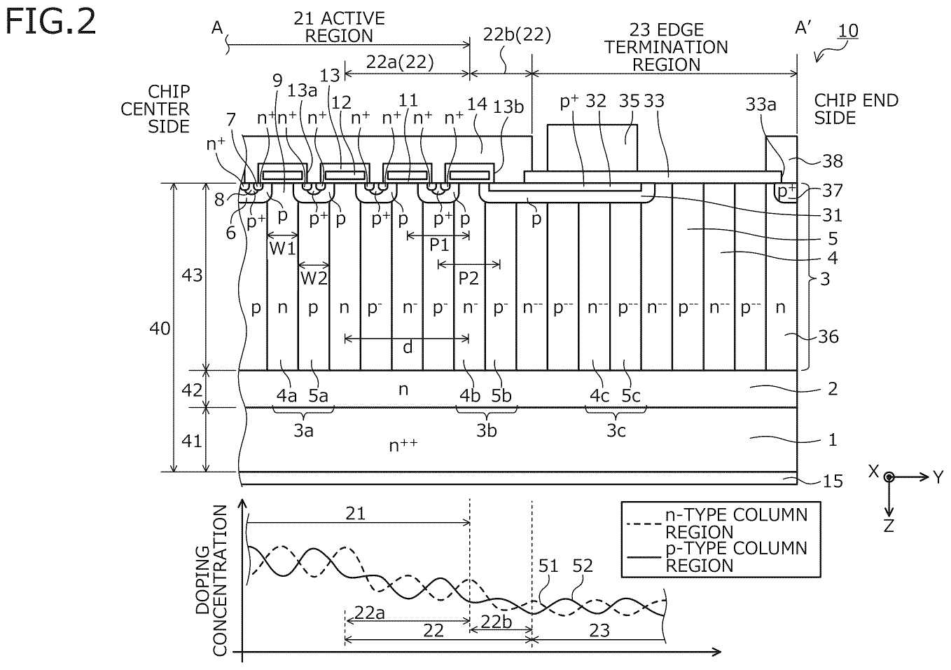

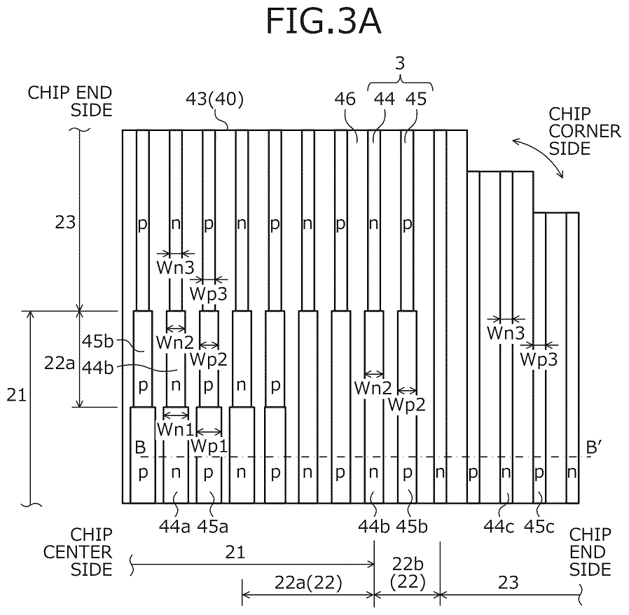

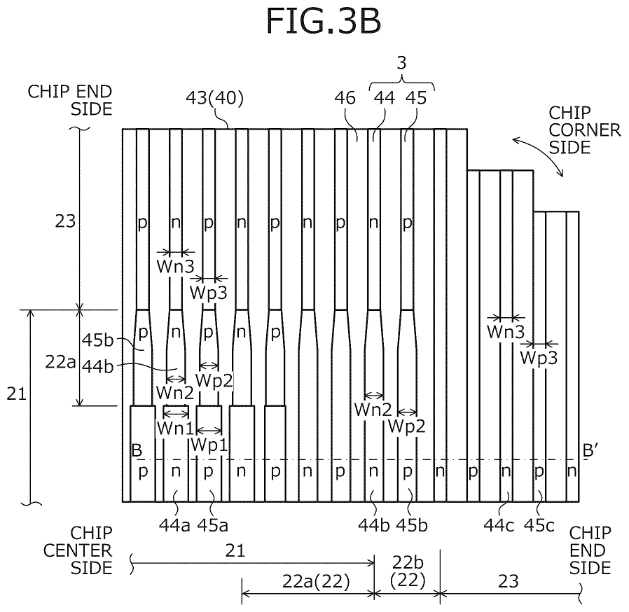

A structure of a semiconductor device according to an embodiment is described. FIG. 1 is a plan view depicting a layout when the semiconductor device according to the embodiment is viewed from a front side of a semiconductor substrate thereof. In FIG. 1, an outer periphery of the active region 21 and an inner periphery of an edge termination region 23 are indicated by dashed lines while an inner periphery of the transition region 22 is indicated by a dotted line. FIG. 2 is a cross-sectional view along cutting line A-A′ in FIG. 1. FIG. 2 schematically depicts corresponding to the cross-section of a semiconductor device 10, doping concentration distributions 51, 52 in the first direction X, estimated from a formation method (multistage epitaxial method) for one stage of a parallel pn layer 3 after thermal diffusion treatment. FIGS. 3A and 3B are plan views depicting examples of states of the semiconductor device according to the embodiment during manufacture.

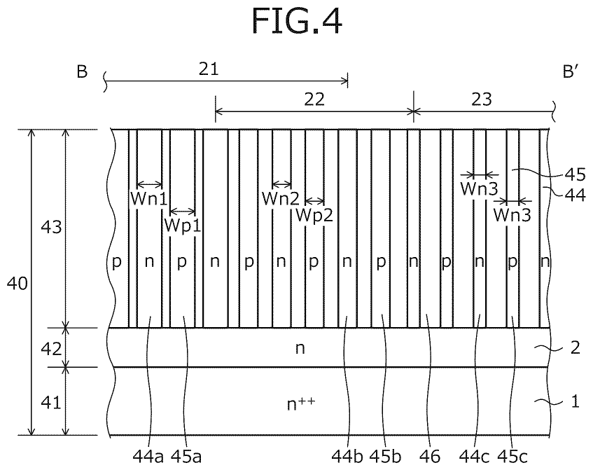

FIGS. 3A and 3B depict examples of layouts of the parallel pn layer 3 (n-type dopant implanted regions 44 and p-type dopant implanted regions 45) before the thermal diffusion treatment. FIG. 4 is a cross-sectional view of the structure along cutting line B-B′ in FIGS. 3A and 3B. The semiconductor device 10 according to the embodiment depicted in FIGS. 1 and 2 is a planar gate MOSFET having a SJ structure in which a drift layer is constituted by the parallel pn layer 3 in the active region 21, the transition region 22, and the edge termination region 23 of a semiconductor substrate (semiconductor chip) 40 containing silicon (Si) as a semiconductor material.

The active region 21 is a region through which a main current (drift current) flows when the MOSFET is on. In the active region 21, multiple unit cells (functional units of a device) each having a same MOSFET structure are disposed adjacent to one another. The active region 21 has a substantially rectangular shape in a plan view of the device and is disposed in substantially a center (chip center) of the semiconductor substrate 40. The active region 21 is a region farther inward on a chip-center side (closer to the chip center) than are centers of outermost ones of multiple gate electrodes 12, the outermost ones being closest to the chip end (end of the semiconductor substrate 40) in the later-described first direction X, and the active region 21 is closer to the chip center than are ends (in a longitudinal direction) of n⁺-type source regions 7 in the later-described second direction Y.

In semiconductor substrate 40, epitaxial layers 42, 43 constituting an n-type buffer region 2 and the parallel pn layer 3 are stacked sequentially, in the order stated, on a front surface of an n⁺⁺-type starting substrate 41 constituting an n⁺⁺-type drain region 1. The semiconductor substrate 40 has, as the front surface, a main surface that is a surface of the epitaxial layer 43 and has, as a back surface, a main surface that is a back surface of the n⁺⁺-type starting substrate 41. In the active region 21, p-type base regions 6, the n⁺-type source regions 7, p⁺-type contact regions 8, and JFET regions 9 configuring a planar gate structure (device structure) are provided between the front surface of the semiconductor substrate 40 and the parallel pn layer 3.

The p-type base regions 6, the n⁺-type source regions 7, the p⁺-type contact regions 8, and the JFET regions 9 are diffused regions formed by ion implantation in surface regions of the epitaxial layer 43 and extend linearly in a longitudinal direction (the later-described first direction X) of later-described n-type column regions 4 and p-type column regions 5. The p-type base regions 6 are provided between the front surface of the semiconductor substrate 40 and the p-type column regions 5, the p-type base regions 6 each having a lower surface (surface facing the n⁺⁺-type drain region 1) in contact with the p-type column regions 5. The p-type base regions 6 have a width (in the first direction X) wider than a width (in the first direction X) of the p-type column regions 5.

The p-type base regions 6, the n⁺-type source regions 7, and the p⁺-type contact regions 8 each have arc-shaped corner portions (boundaries between lower surface and side surfaces) rounded to have a predetermined curvature. The n⁺-type source regions 7 and the p⁺-type contact regions 8 are selectively provided between the front surface of the semiconductor substrate 40 and the p-type base regions 6. The n⁺-type source regions 7 and the p⁺-type contact regions 8 are disposed to be apart from side surfaces of the p-type base regions 6 while peripheries of the n⁺-type source regions 7 and the p⁺-type contact regions 8 are bordered by the p-type base regions 6. The n⁺-type source regions 7 and the p⁺-type contact regions 8 are adjacent to one another.

The n⁺-type source regions 7 and the p⁺-type contact regions 8 are exposed at the front surface of the semiconductor substrate 40 by later-described contact holes 13a. In the contact holes 13a, source contacts are formed by ohmic contacts between a source electrode 14 and the semiconductor substrate 40. The n⁺-type source regions 7 are provide at positions closer to the gate electrodes 12 (positions closer to the side surfaces of the p-type base regions 6) than are the p⁺-type contact regions 8. The p⁺-type contact regions 8 may be omitted. In this instance, instead of the p⁺-type contact regions 8, the p-type base regions 6 reach the front surface of the semiconductor substrate 40 and are exposed by the contact holes 13a.

The JFET regions 9 are n-type regions between adjacent ones of the p-type base regions 6, each of the JFET regions 9 having side surfaces in contact with the p-type base regions 6 and a lower surface in contact with the n-type column regions 4. The JFET regions 9 are adjacent to channels (n-type inversion layer) and form current paths of the drift current. A doping concentration of the JFET regions 9 is at least equal to a doping concentration of the n-type column regions 4, but lower than a doping concentration of the n⁺-type source regions 7. The JFET regions 9 may be configured by the n-type column regions 4, which extend between the p-type base regions 6 adjacent to each other, so as to reach the front surface of the semiconductor substrate 40.

The gate electrodes 12 are provided on the front surface of the semiconductor substrate 40 via gate insulating films 11, and cover regions of the p-type base regions 6 between the n⁺-type source regions 7 and the JFET regions 9, via the gate insulating films 11. The gate electrodes 12 each cover an entire area of the surface of one of the JFET regions 9 via one of the gate insulating films 11, and face one of the n-type column regions 4 in the depth direction Z. A center of each of the gate electrodes 12 in the first direction X substantially coincides with a center (in the first direction X) of a corresponding one of the n-type column regions 4 facing each of the gate electrodes 12 in the depth direction Z. Between centers of any adjacent two of the gate electrodes 12 in the first direction X constitutes one unit cell.

An interlayer insulating film 13 is provided in an entire area of the front surface of the semiconductor substrate 40 and covers the gate electrodes 12. The contact holes 13a are provided in the interlayer insulating film 13 for each of the unit cells. The contact holes 13a expose the n⁺-type source regions 7 and the p⁺-type contact regions 8. The source electrode (first electrode) 14 is provided on the interlayer insulating film 13 so as to be embedded in the contact holes 13a and thereby be in ohmic contact with the n⁺-type source regions 7 and the p⁺-type contact regions 8. The source electrode 14 has substantially a same shape as the shape of the active region 21 in a plan view of the device and covers substantially an entire area of the active region 21.

The transition region 22 has a first portion 22a overlapping the active region 21, and a second portion 22b between the active region 21 and the edge termination region 23. In the transition region 22, the later-described n-type column regions 4 and the p-type column regions 5 are disposed in descending order of doping concentration so that the n-type column regions 4 and the p-type column regions 5 relatively closer to the chip end in a direction from the active region 21 (i.e., the chip center side (inner side)) to the edge termination region 23 (i.e., the chip end side (outer side)) have relatively lower doping concentrations, whereby the transition region 22 has a function of suppressing electric field concentration near a boundary between the active region 21 and the edge termination region 23.

The first portion 22a of the transition region 22 is a portion extending from the end of the active region 21 in the transition region 22 in a direction to the chip center; the first portion 22a overlaps the entire outer periphery of the active region 21 by a predetermined, substantially constant width d. In particular, the first portion 22a of the transition region 22 includes, among the n-type column regions 4 and the p-type column regions 5 in the active region 21, at least one adjacent pair including one of the n-type column regions 4 and one of the p-type column regions 5 adjacent to each other in the first direction X. An inner peripheral end (end facing the chip center) of the first portion 22a of the transition region 22 substantially coincides with a center (center of one of the gate electrodes 12) of a predetermined one of the n-type column regions 4 in the first direction X. The n-type column regions 4 facing the inner peripheral end of the first portion 22a of the transition region 22 (inner periphery end of the transition region 22) in the depth direction Z are the n-type column regions 4a of a later-described first parallel pn layer 3a.

In other words, the first portion 22a of the transition region 22 includes, in the first direction X from the chip end side, at least one unit cell (portion between centers of two of the gate electrodes 12, the two being closest to the chip end in the first direction X and adjacent to each other) and overlaps, in the second direction Y, both longitudinal ends of the unit cell(s) by the predetermined width d. Preferably, with the width d being at least about two times a recursive pitch P1 of the n-type column regions 4, the first portion 22a of the transition region 22 may include two or more unit cells in the first direction X from the chip end side. The width d of the first portion 22a of the transition region 22 is, for example, at least about 5 μm.

While electric field concentration in the transition region 22 and near the transition region 22 may be suppressed to a greater extent the wider is the width d of the first portion 22a of the transition region 22, as described hereinafter, the respective doping concentrations of the n-type column regions 4 and the p-type column regions 5 are relatively lower in the first portion 22a of the transition region 22, whereby the on-resistance increases. Thus, the width d of the first portion 22a of the transition region 22, for example, is in a range of not more than about 50 μm and is suitably set according to the widths W1, W2 and the doping concentrations of the n-type column regions 4 and the p-type column regions 5 in the first portion 22a of the transition region 22.

The second portion 22b of the transition region 22 is a portion extending from the end of the active region 21 in the transition region 22 in a direction to the chip end; the second portion 22b is adjacent to a side of the first portion 22a of the transition region 22, the side facing the chip end. The second portion 22b of the transition region 22 is between the first portion 22a and the edge termination region 23 in the first direction X. The second portion 22b of the transition region 22 is not provided between the active region 21 and the edge termination region 23 in the second direction Y. An outer peripheral end (end facing the chip end) of the second portion 22b of the transition region 22 substantially coincides with an end of the source electrode 14. In an instance in which the outer peripheral end of the second portion 22b of the transition region 22 (outer peripheral end of the transition region 22) does not substantially coincide with pn junctions between the n-type column regions 4 and the p-type column regions 5, a column region facing the outer peripheral end of the second portion 22b of the transition region 22 is one of multiple n-type column regions 4c or one of multiple p-type column regions 5c of a later-described third parallel pn layer 3c.

In the second portion 22b of the transition region 22, between the front surface of the semiconductor substrate 40 and the parallel pn layer 3, an outer peripheral p-type region 31 and an outer peripheral p⁺-type contact region 32 extend from the edge termination region 23. Further, in the second portion 22b of the transition region 22, a contact hole 13b is provided in the interlayer insulating film 13, closer to the chip end than are the gate electrodes 12. The contact hole 13b extends linearly in the first direction X along a boundary between the first portion 22a and the second portion 22b of the transition region 22; the contact hole 13b exposes the outer peripheral p⁺-type contact region 32.

The source electrode 14, which extends toward the chip end from the active region 21, is embedded in the contact hole 13b, whereby a source contact is formed by an ohmic contact between the source electrode 14 and the semiconductor substrate 40 (the outer peripheral p⁺-type contact region 32). The source electrode 14 terminates on a later-described insulating layer 33. The second portion 22b of the transition region 22 has a function of leading out holes (minority carriers) accumulated in the n-type column regions 4 in the edge termination region 23 when the parasitic pn junction diode (body diode) of the MOSFET conducts, the second portion 22b leading the holes out to the source electrode 14 during reverse recovery of the body diode.

The edge termination region 23 is in contact with the second portion 22b of the transition region 22 in the first direction X and is in contact with the active region 21 in the second direction Y. A portion of the edge termination region 23, via the second portion 22b of the transition region 22, surrounds the periphery of the active region 21 in a substantially rectangular shape in a plan view of the device. In the edge termination region 23, the outer peripheral p-type region 31 is selectively provided between the front surface of the semiconductor substrate 40 and the parallel pn layer 3. The outer peripheral p-type region 31, for example, is formed in the epitaxial layer 43 concurrently with the p-type base regions 6 and has substantially a same doping concentration and substantially a same depth as the doping concentration and depth of the p-type base regions 6.

The outer peripheral p-type region 31 surrounds the periphery of the active region 21 in a substantially rectangular shape in a plan view of the device. Longitudinal ends of the p-type base regions 6 of all the unit cells are connected to the outer peripheral p-type region 31. The outer peripheral p-type region 31 is fixed to a potential of the source electrode 14, via the p-type base regions 6 and the outer peripheral p⁺-type contact region 32. The outer peripheral p-type region 31 has a lower surface in contact with the n-type column regions 4 and the p-type column regions 5 in the second portion 22b of the transition region 22 and the edge termination region 23. An outer peripheral end of the outer peripheral p-type region 31 terminates in predetermined ones of the n-type column regions 4.

The outer peripheral p-type region 31 extends in the first direction X, closer to the chip center than is the contact hole 13b and terminates in the second portion 22b of the transition region 22, while in the second direction Y, the outer peripheral p-type region 31 terminates in the active region 21, at the boundary between the active region 21 and the edge termination region 23. An inner peripheral end of the outer peripheral p-type region 31 extending in the first direction X toward the chip center faces, in the depth direction Z, the outermost ones of the gate electrodes 12 closest to the chip end. An inner peripheral end of the outer peripheral p-type region 31 extending in the second direction Y toward the chip center faces, in the depth direction Z, longitudinal ends of all the gate electrodes 12.

Portions of the outer peripheral p-type region 31 facing the gate electrodes 12 in the depth direction Z are free of the n⁺-type source regions 7. The portions of the outer peripheral p-type region 31 facing the gate electrodes 12 in the depth direction Z are free of the n⁺-type source regions 7, whereby the gate electrodes 12 and the outer peripheral p-type region 31 are in contact with each other and pn junctions between the outer peripheral p-type region 31 and the n-type column regions 4 operate as body diodes and thus, hole current may be efficiently discharged in the gate electrodes 12.

Between the front surface of the semiconductor substrate 40 and the outer peripheral p-type region 31, the outer peripheral p⁺-type contact region 32 is provided in contact with the outer peripheral p-type region 31. The outer peripheral p⁺-type contact region 32 is a diffused region formed by ion implantation in a surface region of the epitaxial layer 43 and is in contact with the insulating layer 33 at the front surface of the semiconductor substrate 40. The outer peripheral p⁺-type contact region 32 may be omitted. In this instance, instead of the outer peripheral p⁺-type contact region 32, the outer peripheral p-type region 31 is in contact with the insulating layer 33 at the front surface of the semiconductor substrate 40 and is exposed by the contact hole 13b.

In the edge termination region 23, the front surface of the semiconductor substrate 40 is covered by the insulating layer 33. In the insulating layer 33, for example, a field oxide film and the interlayer insulating film 13 are stacked sequential in the order stated. In the insulating layer 33, a gate polysilicon (poly-Si) wiring layer 34 is provided. On the insulating layer 33, a gate metal wiring layer 35 facing the gate polysilicon wiring layer 34 in the depth direction Z is provided. The gate polysilicon wiring layer 34 and the gate metal wiring layer 35 face the outer peripheral p-type region 31 and the outer peripheral p⁺-type contact region 32, in the depth direction Z.

The gate polysilicon wiring layer 34 and the gate metal wiring layer 35 function as a gate runner. The gate polysilicon wiring layer 34 is disposed only at a position facing the active region 21 in the second direction Y and the longitudinal ends of all the gate electrodes 12 are connected. The gate metal wiring layer 35 surrounds the periphery of the active region 21 in a substantially rectangular shape in a plan view of the device. The gate metal wiring layer 35, via a contact hole (not depicted) of the insulating layer 33, is in contact with the gate polysilicon wiring layer 34 therebelow.

A gate pad 16, for example, in the active region 21 (or spanning the active region 21 to the transition region 22), is provided on the insulating layer 33 so as to be in contact with the gate metal wiring layer 35 (FIG. 1). The gate metal wiring layer 35 and the gate pad 16, for example, are formed concurrently with the source electrode 14. Further, the gate metal wiring layer 35 and the gate pad 16 are electrically insulated from the source electrode 14. The gate pad 16, for example, has a substantially rectangular shape in a plan view of the device, with one side being in direct contact with one side of an inner periphery of the gate metal wiring layer 35 and the remaining three sides facing the source electrode 14 across a predetermined interval intervening therebetween.

Between the parallel pn layer 3 and the chip end is an n-type region 36. The n-type region 36 is a diffused region formed in the epitaxial layer 43 by the multistage epitaxy technique concurrently with the formation of the parallel pn layer 3; n-type region 36 is in contact with the insulating layer 33 at the front surface of the semiconductor substrate 40 and has a lower surface in contact with the n-type buffer region 2. The n-type region 36 is in contact with the parallel pn layer 3 and surrounds a periphery of the parallel pn layer 3 in a substantially rectangular shape in a plan view of the device. The n-type region 36 is exposed at the chip end. The n-type region 36 may have a doping concentration higher than a doping concentration of the n-type column regions 4 (later-described n⁻⁻-type column regions 4c) in the edge termination region 23.

Between the front surface of the semiconductor substrate 40 and the n-type region 36, a p⁺-type channel stopper region 37 is selectively provided so as to be apart from the parallel pn layer 3 while being in contact with the n-type region 36 and exposed at the chip end. The p⁺-type channel stopper region 37 extends along an outer periphery of the chip and, in a plan view of the device, surrounds the periphery of the parallel pn layer 3 in a substantially rectangular shape having, for example, rounded corners (vertices) of a predetermined curvature. The p⁺-type channel stopper region 37, for example, is formed in the epitaxial layer 43 concurrently with the p-type base regions 6 and has substantially a same doping concentration and substantially a same depth as the doping concentration and the depth of the p-type base regions 6.

A channel stopper electrode 38 is provided on the front surface of the semiconductor substrate 40, apart from the gate metal wiring layer 35. The channel stopper electrode 38 is an outermost metal electrode on the front surface of the semiconductor substrate 40 and, for example, is formed concurrently with the source electrode 14. The channel stopper electrode 38 extends along the chip end and surrounds the periphery of the parallel pn layer 3 in a substantially rectangular shape in a plan view of the device. The channel stopper electrode 38 is in contact with the p⁺-type channel stopper region 37 therebelow, via a contact hole 33a of the insulating layer 33. The channel stopper electrode 38 is fixed to a same potential as a potential of a drain electrode 15.

Between the outer peripheral p-type region 31 and the p⁺-type channel stopper region 37, a predetermined voltage withstanding structure (not depicted) such as a field limiting ring (FLR) or a RESURF structure may be disposed between the front surface of the semiconductor substrate 40 and the parallel pn layer 3. In an entire area of the back surface (back surface of the n⁺⁺-type starting substrate 41) of the semiconductor substrate 40, the drain electrode (second electrode) 15 is provided.

In the present embodiment, while the semiconductor substrate (semiconductor chip) 40 containing silicon (Si) as a semiconductor material is used, the semiconductor substrate (semiconductor chip) 40 may contain silicon carbide (SiC) as a semiconductor material and a junction termination extension (JTE) structure may be provided as a voltage withstanding structure in the edge termination region 23.

Spanning the active region 21, the first and second portions 22a, 22b of the transition region 22, and the edge termination region 23, the parallel pn layer 3 is provided in which the n-type column regions (first-conductivity-type regions) 4 and the p-type column regions (second-conductivity-type regions) 5 are disposed repeatedly alternating with one another in the first direction X parallel to the front surface of the semiconductor substrate 40. Spanning the active region 21, the first portion 22a of the transition region 22, and the edge termination region 23, the n-type column regions 4 and the p-type column regions 5 extend linearly in the second direction Y, which is parallel to the front surface of the semiconductor substrate 40 and orthogonal to the first direction X; the n-type column regions 4 and the p-type column regions 5 form square-shaped columns that extend linearly in the depth direction Z.

All the n-type column regions 4 and the p-type column regions 5 are disposed having, in the lateral direction (the first direction X), substantially the same widths W1, W2 and substantially the same recursive pitches P1, P2 while in the longitudinal direction (the second direction Y), spanning the active region 21, the first portion 22a of the transition region 22, and the edge termination region 23, the n-type column regions 4 and the p-type column regions 5 extend linearly having substantially the same widths W1, W2 and in the depth direction Z, extend linearly having substantially the same widths W1, W2. In other words, the n-type column regions 4 and the p-type column regions 5 form the same stripe pattern in both a plan view and a cross-sectional view thereof.

The n-type column regions 4 and the p-type column regions 5 are formed using a multistage epitaxy technique and by ion-implanting a dopant in the non-doped epitaxial layer 43. The multistage epitaxy technique is a method in which an epitaxial layer is grown by multiple stages of epitaxy until the epitaxial layer has a predetermined thickness and at each stage of epitaxy, dopant implanted regions of a predetermined conductivity type are selectively formed in the epitaxial layer, by photolithography and ion implantation, so as to face dopant implanted regions of a same conductivity type therebelow in the depth direction Z.

The parallel pn layer 3 exhibits the n-type doping concentration distribution (first-conductivity-type doping concentration distribution) 51 and the p-type doping concentration distribution (second-conductivity-type doping concentration distribution) 52 in which, in the active region 21, a portion (hereinafter, first parallel pn layer) 3a thereof other than the first portion 22a of the transition region 22 has a relatively high doping concentration, the transition region 22 has a doping concentration lower than the doping concentration of the first parallel pn layer 3a, and a portion (hereinafter, third parallel pn layer) 3c of the edge termination region 23 has a relatively low doping concentration. In the second portion 22b of the transition region 22, the column regions 4, 5 are disposed in descending order of doping concentration so that the column regions 4, 5 relatively closer to the chip end in the first direction X have relatively lower doping concentrations.

The n-type doping concentration distribution 51 and the p-type doping concentration distribution 52 are formed at each stage of the epitaxial layer 43 grown by multistage epitaxy. The doping concentration distributions of the column regions 4, 5 at each stage of the epitaxial layer 43 exhibit Gaussian distribution with the depth of the range of the ion implantation as a vertex. The n-type doping concentration distribution 51 is formed by connected Gaussian distributions exhibited by the n-type column regions 4 adjacent to one another in the first direction X. The p-type doping concentration distribution 52 is formed by connected Gaussian distributions exhibited by the p-type column regions 5 adjacent to one another in the first direction X.

A point of intersection between the n-type doping concentration distribution 51 and the p-type doping concentration distribution 52 corresponds to an interface between one of the n-type column regions 4 and an adjacent one of the p-type column regions 5. Near the point of intersection between the n-type doping concentration distribution 51 and the p-type doping concentration distribution 52, electrons in the n-type column regions 4 and holes in the p-type column regions 5 recombine with each other, disappear and are nearly depleted. Due to a later-described second parallel pn layer 3b, in the doping concentration distributions 51, 52, the difference in doping concentrations of column regions of the same conductivity type between first and third parallel pn layers 3a, 3c becomes smaller stepwise in a direction to the chip end.

Ion implantation masks for forming the n-type column regions 4 and the p-type column regions 5 have opening patterns in which the opening widths in portions having relatively lower doping concentrations are relatively narrower. A dopant of a predetermined conductivity type is ion-implanted by a same dose amount in an entire area of the surface of the non-doped epitaxial layer 43 using the ion implantation masks, thereby selectively forming column regions of a predetermined conductivity type. Effective doping concentrations of the n-type column regions 4 and the p-type column regions 5 are relatively lower in portions where the opening width of the ion implantation mask is relatively narrower.

A ratio of relatively high and low doping concentrations in the column regions coincides with a ratio of relatively wide and narrow opening widths of the ion implantation masks. Thus, in the parallel pn layer 3, when the doping concentration of the column regions of the first parallel pn layer 3a is assumed as a reference value (=1 time), the doping concentration of the column regions of the later-described second parallel pn layer 3b is assumed to be reduced to 0.75 times the reference value, and the doping concentration of the column regions of the third parallel pn layer 3c is assumed to be reduced to 0.5 times the reference value, the ion implantation masks suffice to have an opening pattern in which the opening widths are set to a ratio of 1:0.75:0.5 at corresponding locations in the ion implantation masks.

In particular, in the parallel pn layer 3, n-type column regions 4a (the n-type column regions 4: first first-conductivity-type regions) and p-type column regions 5a (the p-type column regions 5: first second-conductivity-type regions) in the first parallel pn layer 3a (portion of the active region 21 other than the first portion 22a of the transition region 22) have substantially the same widths W1, W2 and substantially the same doping concentrations. The n-type column regions 4a and the p-type column regions 5a that are adjacent to one another have balanced charge therebetween at least on a plane parallel to the main surface of the semiconductor substrate 40. The n-type column regions 4 and the p-type column regions 5, respectively, have relatively high doping concentrations in the n-type column regions 4a and the p-type column regions 5a.

In the parallel pn layer 3, n⁻-type column regions 4b (the n-type column regions 4: second first-conductivity-type regions) and p⁻-type column regions 5b (the p-type column regions 5: second second-conductivity-type regions) in the first and second portions 22a, 22b (hereinafter, the second parallel pn layer 3b) of the transition region 22 have substantially the same widths W1, W2 and substantially the same doping concentrations. The n-type column regions 4b and the p⁻-type column regions 5b that are adjacent to one another have roughly balanced charge therebetween. The n⁻-type column regions 4b and the p-type column regions 5b have doping concentrations that are, respectively, lower than the doping concentrations of the n-type column regions 4a and the p-type column regions 5a in the active region 21 (relatively closer to the chip center).

The first portion 22a of the transition region 22 overlaps an entire periphery of an outer peripheral portion of the active region 21. Thus, in a center portion of the active region 21 (portion of the active region 21 other than the first portion 22a of the transition region 22 and in chip center), the first parallel pn layer 3a formed by the n-type column regions 4a and the p-type column regions 5a is disposed, while the second parallel pn layer 3b formed by the n⁻-type column regions 4b and the p⁻-type column regions 5b is disposed over the entire periphery of the outer peripheral portion of the active region 21. The second parallel pn layer 3b surrounds a periphery of the first parallel pn layer 3a in a plan view of the device.

In the second portion 22b of the transition region 22, the n⁻-type column regions 4b and the p⁻-type column regions 5b are disposed in descending order of doping concentration so that the n′-type column regions 4b and the p-type column regions 5b relatively closer to the chip end in the first direction X have relatively lower doping concentrations. In the first portion 22a of the transition region 22 as well, the n⁻-type column regions 4b and the p⁻-type column regions 5b may be disposed in descending order of doping concentration so that the n⁻-type column regions 4b and the p⁻-type column regions 5b relatively closer to the chip end in the first direction X have relatively lower doping concentrations. In other words, the respective doping concentrations of the n⁻-type column regions 4b and the p⁻-type column regions 5b in the transition region 22 may be lower stepwise the closer the n⁻-type column regions 4b and the p⁻-type column regions 5b are to the chip end in the first direction X.

In the parallel pn layer 3, the n⁻⁻-type column regions 4c (the n-type column regions 4: third first-conductivity-type regions) and the p⁻⁻-type column regions 5c (the p-type column regions 5: third second-conductivity-type regions) of the third parallel pn layer 3c (portion in the edge termination region 23) have substantially the same widths W1, W2 and substantially the same doping concentrations. The n⁻⁻-type column regions 4c and the p⁻⁻-type column regions 5c that are adjacent to one another have balanced charge therebetween. The n⁻⁻-type column regions 4c and the p⁻⁻-type column regions 5c have doping concentrations that are, respectively, lower than the doping concentrations of the n⁻-type column regions 4b and the p⁻-type column regions 5b in the transition region 22.

Here, balanced charge means that the amount of charge expressed by a product obtained by multiplying the carrier concentration (concentration of activated dopant) and the width W1 of the n-type column regions 4 and the amount of charge obtained by multiplying the carrier concentration and the width W2 of the p-type column regions 5 are substantially the same and the amount of charge of one of the n-type column regions 4 and the amount of charge of an adjacent one of the p-type column regions 5 are in equilibrium with each other. Substantially the same doping concentration (the carrier concentration) and substantially the same width mean, respectively, the same doping concentration and the same width within a range including an allowable error due to process variation.

In forming the parallel pn layer 3 by the multistage epitaxy technique, in each stage of the epitaxial layer 43, the n-type dopant implanted regions 44 each are formed in a center (in the first direction X) of a corresponding formation region of the n-type column regions 4 by ion implantation using the ion implantation masks opened at portions corresponding to the formation regions of the n-type column regions 4. In each stage of the epitaxial layer 43, the p-type dopant implanted regions 45 are each formed in a center (in the first direction X) of a corresponding formation region of the p-type column regions 5 by ion implantation using the ion implantation masks opened at portions corresponding to the formation regions of the p-type column regions 5. Thereafter, a thermal diffusion treatment for diffusing and activating the dopants in the epitaxial layer 43 is performed.

The n-type dopant implanted regions 44 have: portions 44a in the center portion of the active region 21, each having the width Wn1, which is widest, portions 44b in the transition region 22, each having the width Wn2, which is narrower than the width Wn1 of the portions 44a in the center portion of the active region 21, and portions 44c in the edge termination region 23, each having the width Wn3, which is narrowest. The portions 44a, 44b, 44c of the n-type dopant implanted regions 44 have the widths Wn1, Wn2, Wn3 that differ and are formed concurrently under the same ion implantation conditions (dose amount, acceleration energy). The portions 44a, 44b, 44c of the n-type dopant implanted regions 44 in the active region 21 and the transition region 22 are connected to one another in the second direction Y and respective centers (in the first direction X) of the portions 44a, 44b, 44c are at substantially the same position.

The p-type dopant implanted regions 45 have: portions 45a in the center portion (portion other than the first portion 22a of the transition region 22) of the active region 21, each having the width Wp1, which is widest, portions 45b in the transition region 22, each having the width Wp2, which is narrower than the width Wp1 of the portions 45a in the center portion of the active region 21, portions 45c in the edge termination region 23, each having the width Wp3, which is narrowest. The portions 45a, 45b, 45c of the p-type dopant implanted regions 45 have the widths Wp1, Wp2, Wp3 that differ and are formed concurrently under the same ion implantation conditions (dose amount, acceleration energy). The portions 45a, 45b, 45c of the p-type dopant implanted regions 45 in the active region 21 and the transition region 22 are connected to one another in the second direction Y and respective centers (in the first direction X) of the portions 45a, 45b, 45c are at substantially the same position.

Each stage of the parallel pn layer 3 (the epitaxial layer 43) before the thermal diffusion treatment is in a state in which the n-type dopant implanted regions 44 and the p-type dopant implanted regions 45 are disposed alternating with one another repeatedly in the first direction X, with non-doped regions (regions of the non-doped epitaxial layer 43 free of implanted dopants) 46 intervening therebetween (FIGS. 3A and 3B). The non-doped regions 46 are each left in a stripe-like shape with a varying width and extending, in the second direction Y. The n-type dopant implanted regions 4, at portions thereof adjacent to the p-type dopant implanted regions 45, have the widths Wn1, Wn2, Wn3 and the dose amount of an n-type dopant that are substantially the same as the widths Wp1, Wp2, Wp3 and the dose amount of an p-type dopant of the p-type dopant implanted regions 45 adjacent thereto.

FIGS. 3A and 3B depict a vicinity of a corner (vertex of a rectangle: chip corner) of the semiconductor substrate 40. In FIGS. 3A, 3B, and 4, in the epitaxial layer 43, portions having an “n” or a “p” are, respectively, the n-type dopant implanted regions 44 and the p-type dopant implanted regions 45 while portions without an “n” or a “p” are the non-doped regions 46. The portions 44a, 44b, 44c of the n-type dopant implanted regions 44 have, respectively, the differing widths Wn1, Wn2, Wn3 and form substantially rectangular shapes extending in the second direction Y, in a plan view of the device. The portions 45a, 45b, 45c of the p-type dopant implanted regions 45 have, respectively, the widths Wp1, Wp2, Wp3 and form substantially rectangular shapes extending in the second direction Y, in a plan view of the device (FIG. 3A).

The portions 44b, 45b of the n-type dopant implanted regions 44 and the p-type dopant implanted regions 45 in the transition region 22 may have longitudinal ends forming a substantially rectangular shape on the active region 21 side and longitudinal ends forming, on the edge termination region 23 side, a tapered shape (trapezoid) in which the widths Wn2, Wp2 narrow along a direction to the edge termination region 23 (FIG. 3B). The longitudinal ends of the portions 44b, 45b of the n-type dopant implanted regions 44 and the p-type dopant implanted regions 45 in the transition region 22 (the longitudinal ends on the edge termination region 23 side) are tapered, whereby the doping concentrations (the amounts of charge) of the n-type column regions 4 and the p-type column regions 5 that are adjacent to one another change gradually in the longitudinal direction and thus, unbalanced charge between the n-type column regions 4 and the p-type column regions 5 that are adjacent to one another does not easily occur, thereby enabling suppression of electric field concentration.

The n-type dopant implanted regions 44 and the p-type dopant implanted regions 45, which terminate near the corners of the semiconductor substrate 40, have lengths in the longitudinal direction (the second direction Y) that may be relatively shorter according to the curvature of corners of the p⁺-type channel stopper region 37. In this instance, the lengths (in the longitudinal direction) of the n-type column regions 4 and the p-type column regions 5 that terminate near the corners of the semiconductor substrate 40 are relatively shorter according to the curvature of the corners of the p⁺-type channel stopper region 37. As a result, the amount of charge of the n-type column regions 4 and the amount of charge of the p-type column regions 5 near the corners of the semiconductor substrate 40 is adjusted, thereby enabling suppression of electric field concentration near the corners of the semiconductor substrate 40.

By the later-described thermal diffusion treatment, the n-type dopant implanted regions 44 and the p-type dopant implanted regions 45 of the stages of the epitaxial layer 43 are diffused and become in equilibrium in the non-doped regions 46 adjacent thereto. The n-type dopant implanted regions 44 of each stage of the epitaxial layer 43 are connected to one another in the depth direction Z. The p-type dopant implanted regions 45 of each of the stages of the epitaxial layer 43 are connected to one another in the depth direction Z. As a result, the n-type dopant implanted regions 44 and the p-type dopant implanted regions 45 of each of the stages of the epitaxial layer 43 constitute, respectively, the n-type column regions 4 and the p-type column regions 5 with substantially the same widths W1, W2.

In an entire area of the parallel pn layer 3, the n-type column regions 4 and the p-type column regions 5 that are adjacent to one another have roughly balanced charge therebetween. The non-doped regions 46 are provided between the n-type dopant implanted regions 44 and the p-type dopant implanted regions 45, whereby excessive widening of a width in the first direction X of a region nearly depleted and formed at interfaces between the n-type column regions 4 and the p-type column regions 5 may be suppressed. As a result, the parallel pn layer 3 configured by the n-type column regions 4 and the p-type column regions 5 exhibits the n-type doping concentration distribution 51 and the p-type doping concentration distribution 52 in which the doping concentration is relatively high in the active region 21, progressively (continuously or discontinuously but as a whole gradually) decreases in the transition region 22 in a direction from the chip center to the chip end, and is relatively low in the edge termination region 23.

While not particularly limited hereto, for example, in an instance in which the semiconductor device 10 according to the embodiment (SJ-MOSFET) has a 650V class semiconductor device, dimensions and doping concentrations of regions have the following values. The doping concentration of the p-type base regions 6, the outer peripheral p-type region 31, and the p⁺-type channel stopper region 37 is 8.0×10¹⁹/cm³. The thickness of the parallel pn layer 3 is 40.0 μm. The widths W1, W2 of the n-type column regions 4 and the p-type column regions 5 of the parallel pn layer 3 are all substantially the same in the active region 21, the transition region 22, and the edge termination region 23, are 6.0 μm (the recursive pitches P1, P2 are 12.0 μm), and preferably may be 4.0 μm (the recursive pitches P1, P2 8.0 μm).

In an instance in which the n-type column regions 4 and the p-type column regions 5 of the parallel pn layer 3 are formed by ion implantation of phosphorus (P) and boron (B), respectively, the phosphorus concentration of the n-type column regions 4a of the first parallel pn layer 3a is assumed to be 1.0×10¹⁶/cm³ as a reference value and the boron concentration of the p-type column regions 5a to be 1.0×10¹⁶/cm³ as a reference value. In the second parallel pn layer 3b, the phosphorus concentration of the n-type column regions 4b and the boron concentration of the p-type column regions 5b are assumed to be ¾ times the corresponding reference values while in the third parallel pn layer 3c, the phosphorus concentration of the n⁻⁻-type column regions 4c and the boron concentration of the p⁻⁻-type column regions 5c are assumed to be ½ times the corresponding reference values. The width d of the first portion 22a of the transition region 22 is in a range of 5 μm to 50 μm.

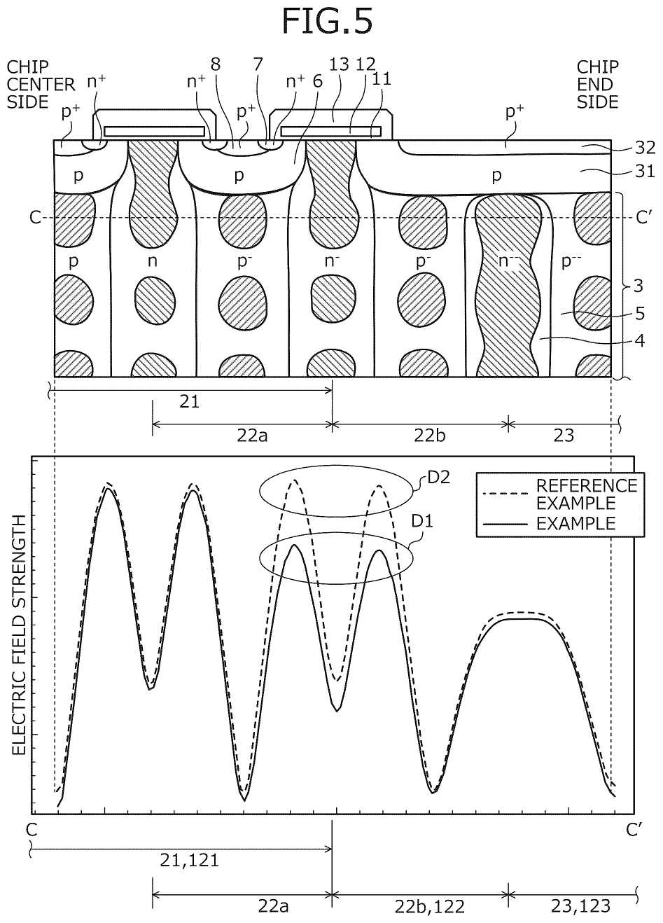

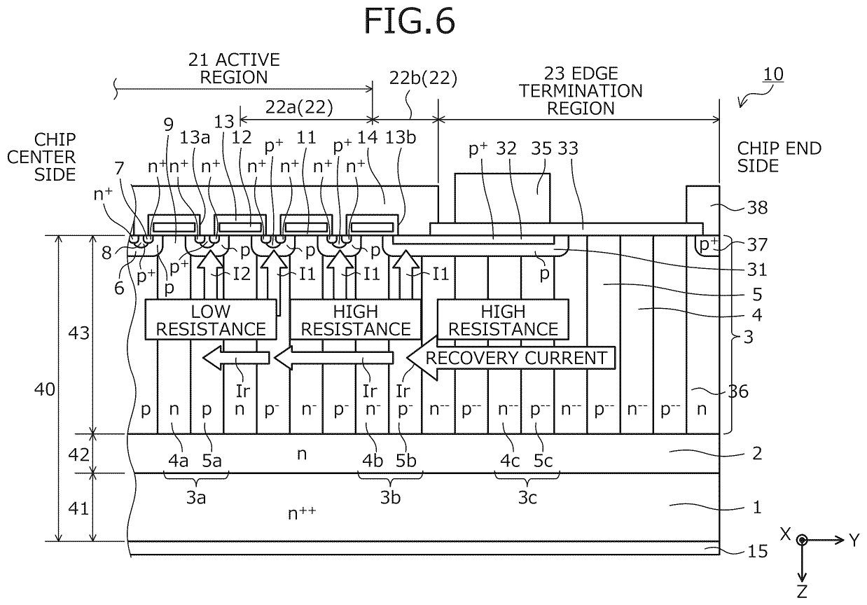

Operation of the semiconductor device 10 according to the embodiment is described. FIG. 5 is a characteristics diagram showing results of simulation of electric field strength during reverse recover of body diodes of an example and the reference example. FIG. 6 is a diagram schematically depicting a state during reverse recovery of a body diode of the semiconductor device according to the embodiment. In FIG. 5, the example corresponds to the semiconductor device 10 according to the embodiment (refer to FIG. 1) and the reference example corresponds to the semiconductor device 110 according to the reference example (refer to FIG. 7). A state during reverse recovery of a body diode of the semiconductor device 110 according to the reference example is depicted in FIG. 7.

FIG. 5 depicts the state of electric field strength corresponding to a cross-section of the structure near an upper surface (surface facing the n⁺-type source regions 7) of the parallel pn layer 3 in the outer peripheral portion of the active region 21 of the example. In FIG. 5, portions where the doping concentration is relatively high near vertices (depth positions of the range of the ion implantation of the n-type dopant) of the Gaussian distribution of the n-type doping concentration distribution 51 exhibited by the n-type column regions 4 of the parallel pn layer 3 and portions where the doping concentration is relatively high near vertices (depth positions of the range of the ion implantation of the p-type dopant) of the Gaussian distribution of the p-type doping concentration distribution 52 exhibited by the p-type column regions 5 of the parallel pn layer 3 indicated by different hatching patterns.

FIG. 5 depicts the results of simulation of the electric field strength distribution along cutting line C-C′ in FIG. 5. FIG. 5 further depicts, for comparison, results of simulation of electric field strength distribution in the reference example under the same condition as the conditions of the example. In the example, the first portion 22a of the transition region 22 is simplified and includes fewer unit cells than in FIG. 2. In FIG. 5, a horizontal axis corresponds to position in a horizontal direction in the cross-section of the structure. In FIG. 5, a vertical axis indicates a relative ratio of the electric field strength of the example to the electric field strength of the reference example.

In the semiconductor device 10 according to the embodiment, when voltage that is positive with respect to the source electrode 14 is applied to the drain electrode 15 and voltage that is at least equal to a gate threshold voltage is applied to the gate electrodes 12, channels (n-type inversion layer) are formed in regions of the p-type base regions 6 between the n⁺-type source regions 7 and the JFET regions 9. As a result, drift current (main current) flows from the n⁺-type drain region, through the n-type buffer region 2, the n-type column regions 4, and the channels, to the n⁺-type source regions 7 and the MOSFET turns on.

On the other hand, when voltage that is positive with respect to the source electrode 14 is applied to the drain electrode 15 and voltage that is less than the gate threshold voltage is applied to the gate electrodes 12, the pn junctions between the p-type base regions 6, the p-type column regions 5, and the n-type column regions 4 are reverse biased, whereby the MOSFET maintains the off-state. A depletion layer spreads in vertical directions (directions toward the source electrode 14 and the drain electrode 15) from the pn junctions, and a predetermined breakdown voltage of the active region 21 is ensured. The depletion layer further spreads in a horizontal direction to the chip end and a predetermined breakdown voltage of the edge termination region 23 is ensured.

In the edge termination region 23, the doping concentrations of the n-type column regions 4 and the p-type column regions 5 are set relatively low while the breakdown voltage of the edge termination region 23 is set to be higher than the breakdown voltage of the active region 21. In the edge termination region 23, even when the doping concentrations of the n-type column regions 4 and the p-type column regions 5 are relatively low, the first portion 22a of the transition region 22 is disposed overlapping the entire periphery of the outer peripheral portion of the active region 21, whereby electric field concentration at the boundary between the active region 21 and the edge termination region 23 and at the second portion 22b of the transition region 22 may be suppressed.

One reason for this is that, in the first portion 22a of the transition region 22, the doping concentrations of the n-type column regions 4 and the p-type column regions 5 progressively decrease in a direction from the chip center to the chip end. Thus, even when the difference in doping concentrations of column regions of the same conductivity type is large between the active region 21 and the edge termination region 23, the doping concentration gradient is gradual at the boundary between the active region 21 and the edge termination region 23 and in the second portion 22b of the transition region 22, and in these portions, unbalanced charge between the n-type column regions 4 and the p-type column regions 5 adjacent to one another does not easily occur.

As a result, even when biases in the amounts of charge of the column regions 4, 5 due to process variation and the like occur, electric field concentration at the boundary between the active region 21 and the edge termination region 23 and in the second portion 22b of the transition region 22 may be suppressed. It was confirmed by the present inventor that by disposing the first portion 22a of the transition region 22, the electric field strength (vertices D1 in the electric field strength distribution exhibited by the example in FIG. 5) at the pn junctions between the n-type column regions 4 and the p-type column regions 5 near the boundary between the active region 21 and the edge termination region 23 becomes smaller than the electric field strength of the pn junctions between the n-type column regions 4 and the p-type column regions 5 on the chip center side of the active region 21.

Further, during reverse recovery of a body diode of the MOSFET, holes accumulated in the n⁻⁻-type column regions 4c in the edge termination region 23 when the body diode conducts become recovery (reverse recovery) current Ir and flow toward the active region 21. At this time, in the edge termination region 23, even when avalanche breakdown occurs and the recovery current Ir increases, the first portion 22a of the transition region 22 is disposed overlapping the entire periphery of the outer peripheral portion of the active region 21, whereby concentration of a large current (the recovery current Ir) in the active region 21 may be suppressed (FIG. 6).

In the transition region 22, the column regions 4, 5 have doping concentrations that are relatively low and resistances that are relatively high as compared to the doping concentrations and the resistances in the active region 21. Furthermore, the transition region 22, at the first portion 22a thereof, overlaps the entire periphery of the outer peripheral portion of the active region 21 and thereby has a relatively wide width. The recovery current Ir may be dispersed by a high-resistance path I1 through the source contacts of the transition region 22 to the source electrode 14 and thus, the recovery current Ir flowing on a low-resistance path I2 through the p-type base regions 6 in the center portion of the active region 21 to the source electrode 14 may be reduced.

In contrast, in the semiconductor device 110 according to the reference example (refer to FIG. 7), the transition region 122, which has a relatively narrow width, is disposed only in portions between the active region 121 and the edge termination region 123. Thus, when the doping concentrations of the n-type column regions 104 and the p-type column regions 105 in the edge termination region 123 are relatively low, a steep doping concentration gradient occurs near the boundary between the active region 121 and the edge termination region 123, and in this portion, the n-type column regions 104 and the p-type column regions 105 that are adjacent to one another tend to have unbalanced charge therebetween.

Thus, when the amount of charge of the column regions 104, 105 is biased due to process variation, electric field concentrates locally near the boundary between the active region 121 and the edge termination region 123. The electric field strength (vertices D2 of the electric field strength distribution exhibited by the reference example in FIG. 5) of the pn junctions between the n-type column regions 104 and the p-type column regions 105 near the boundary between the active region 121 and the edge termination region 123 was confirmed by the present inventor to exhibit substantially a same maximum electric field strength as the maximum electric field strength of the pn junctions between the n-type column regions 104 and the p-type column regions 105 on the chip center side of the active region 121.

Further, in the semiconductor device 110 according to the reference example, the recovery current Ir of the body diode tends to flow in the active region 121, which has a relatively low resistance as compared to the transition region 122 and the edge termination region 123. In the edge termination region 123, when avalanche breakdown occurs and the recovery current Ir increases, large current (the recovery current Ir) concentrates on the path I101 that has high resistance and passes through the source contacts of the transition region 122 to the source electrode 114 and on the path I102 that has low resistance and passes through the p-type base regions 106 in the outer peripheral portion of the active region 121, to the source electrode 114.

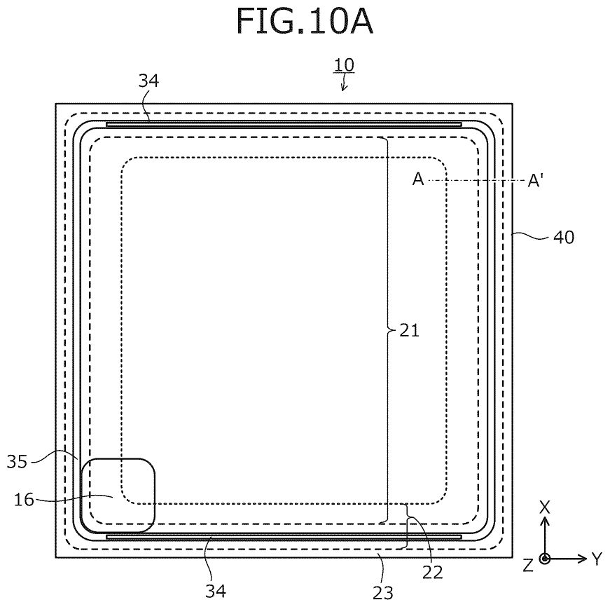

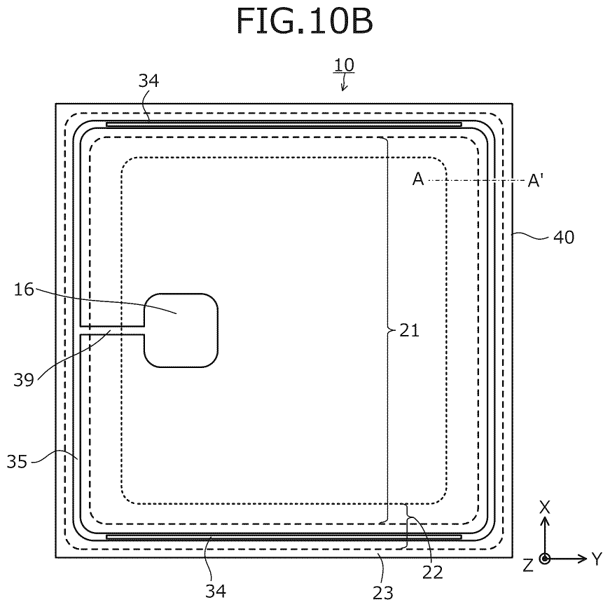

FIG. 10A is a plan view depicting another example of a layout when the semiconductor device according to the embodiment is viewed from the front side of the semiconductor substrate thereof. In FIG. 10A, similar to FIG. 1, the outer periphery of the active region 21 and the inner periphery of the edge termination region 23 are indicated by dashed lines while the inner periphery of the transition region 22 is indicated by a dotted line. FIG. 10A differs from FIG. 1 in that the gate pad 16 is provided so as to be in contact with a corner portion (vertex portion) of the gate metal wiring layer 35. In this instance, for example, the gate pad 16 has one corner portion and two sides common to said corner portion that are in direct contact with a corresponding corner portion and two corresponding sides of the gate metal wiring layer 35; the gate pad 16 further has two sides that face the source electrode 14 with a predetermined interval intervening therebetween. The gate metal wiring layer 35 and the gate pad 16, for example, are formed concurrently with the source electrode 14. Further, the gate metal wiring layer 35 and the gate pad 16 are provided electrically insulated from the source electrode 14. Even when the gate pad 16 is be provided in contact with a corner portion of the gate metal wiring layer 35, effects similar to the effects in FIG. 1 may be obtained.

FIG. 10B is a plan view depicting another example of a layout when the semiconductor device according to the embodiment is viewed from the front side of the semiconductor substrate. In FIG. 10B, similar to FIG. 1, the outer periphery of the active region 21 and the inner periphery of the edge termination region 23 are indicated by dashed lines while the inner periphery of the transition region 22 is indicated by a dotted line. FIG. 10B differs from FIG. 1 in that the gate pad 16 is apart from the gate metal wiring layer 35 while the gate pad 16 and the gate metal wiring layer 35 are electrically connected via a gate metal wiring layer extension portion 39 extending on the insulating layer 33. In this instance, for example, the gate pad 16, at nearly an entire periphery thereof other than a location connected to the gate metal wiring layer extension portion 39, faces the source electrode 14 across a predetermined interval intervening therebetween. The gate metal wiring layer 35, the gate metal wiring layer extension portion 39, and the gate pad 16, for example, are formed concurrently with the source electrode 14. Further, the gate metal wiring layer 35, the gate metal wiring layer extension portion 39, and the gate pad 16 are electrically insulated from the source electrode 14. Even when the gate pad 16 is provided connected to the gate metal wiring layer 35 via the gate metal wiring layer extension portion 39, effects similar to the effects in FIG. 1 may be obtained.

In the foregoing, as described, according to the embodiment, the doping concentration of the column regions configuring the parallel pn layer is relatively high in the center portion of the active region, is lower in the first portion of the transition region than in the center portion of the active region, and is relatively low in the edge termination region. The first portion of the transition region is disposed overlapping the outer peripheral portion of the active region and includes at least one adjacent pair including one of the n-type column regions in active region and an adjacent one of the p-type column regions in active region.

Even when the difference in doping concentrations of column regions of the same conductivity type in the parallel pn layer is large between the active region and the edge termination region, in the transition region, the doping concentration gradient is gradual, and in this portion, unbalanced charge does not easily occur between the n-type column regions and the p-type column regions that are adjacent to each other. Thus, even when biases in the amount of charge of the columns occur due to process variation and the like, a concentration of electric field near the boundary between the active region and the edge termination region is suppressed and decreases in the breakdown voltage may be suppressed.

Further, the doping concentrations of the n-type column regions and the p-type column regions in the edge termination region may be suitably set and thus, design of the edge termination region is facilitated, punch-through of the depletion layer that spreads in a horizontal direction in the edge termination region when the MOSFET is off is prevented, thereby enabling a predetermined breakdown voltage to be ensured. Thus, local concentration of electric field in the edge termination region is suppressed, enabling destruction of the semiconductor device due to avalanche breakdown to be suppressed. Further, increases in the size of the semiconductor device may be suppressed.

In the foregoing, the present invention is not limited to the embodiments described and various modification not departing from the spirit of the invention are possible. For example, in the embodiments described, dimensions and doping concentrations of regions, etc. are variously set according to necessary specifications. Further, in the embodiments, while the first conductivity type is assumed to be an n-type and the second conductivity type is assumed to be a p-type, the present invention is similarly implemented when the first conductivity type is a p-type and the second conductivity type is an n-type.

Further, while the present invention is described taking, as an example, a planar gate MOSFET with the SJ structure having the drift layer as the parallel pn layer 3 in the active region 21, the transition region 22, and the edge termination region 23 of the semiconductor substrate (semiconductor chip) 40 containing silicon (Si) as a semiconductor material, a trench gate MOSFET is further applicable. Furthermore, silicon carbide (SiC), gallium nitride (GaN), or the like may be used as a semiconductor material of the semiconductor substrate.

According to the invention described above, even when the difference in doping concentrations of regions of the same conductivity type in the parallel pn layer is large between the active region and the edge termination region, in the transition region, the doping concentration gradient is gradual and unbalanced charge does not easily occur between the first-conductivity-type regions and the second-conductivity-type regions that are adjacent to each other.

The semiconductor device according to the present invention achieves an effect in that local concentration of electric field may be suppressed.

As described, the semiconductor device according to the present invention is useful for semiconductor devices that emphasize breakdown voltage characteristics and is particularly suitable for semiconductor devices used for automotive applications (vehicle applications).

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having a first main surface and a second main surface opposite to each other, the semiconductor substrate further having an active region; a termination region disposed outside the active region, surrounding a periphery of the active region in a plan view of the semiconductor device; and a transition region between the active region and the termination region;
a parallel pn layer in which a plurality of first-conductivity-type regions and a plurality of second-conductivity-type regions are disposed adjacent to and repeatedly alternating with one another in a direction parallel to the first main surface of the semiconductor substrate, the parallel pn layer being provided in the semiconductor substrate, in the active region, the transition region, and the termination region;
a device structure provided in the active region, between the first main surface of the semiconductor substrate and the parallel pn layer;
a first electrode provided at the first main surface of the semiconductor substrate and electrically connected to the device structure; and
a second electrode provided at the second main surface of the semiconductor substrate, wherein
the transition region overlaps an outer peripheral portion of the active region, and includes at least one adjacent pair of conductivity-type regions that includes one of the plurality of first-conductivity-type regions and one of the plurality of second-conductivity-type regions, which are adjacent to each other in the active region,
the parallel pn layer exhibits:
a first-conductivity-type doping concentration distribution in which a first-conductivity-type doping concentration is relatively high in a center portion of the active region, the center portion being farther from a semiconductor substrate end than is the transition region in said direction parallel to the first main surface of the semiconductor substrate, the first-conductivity-type doping concentration progressively decreases in the transition region in a direction from the active region to the termination region, and the first-conductivity-type doping concentration is relatively low in the termination region, and
a second-conductivity-type doping concentration distribution in which a second-conductivity-type doping concentration is relatively high in the center portion of the active region, the second-conductivity-type doping concentration progressively decreases in the transition region in the direction from the active region to the termination region, and the second-conductivity-type doping concentration is relatively low in the termination region.

2. The semiconductor device according to claim 1, wherein the transition region overlaps the active region by a width in a range of 5 μm to 50 μm from an outer periphery of the active region.

3. The semiconductor device according to claim 1, wherein
the plurality of first-conductivity-type regions includes:
a plurality of first first-conductivity-type regions disposed in the active region;
a plurality of second first-conductivity-type regions disposed in the transition region, the first-conductivity-type doping concentration of the plurality of second first-conductivity-type regions being lower than the first-conductivity-type doping concentration of the plurality of first first-conductivity-type regions; and
a plurality of third first-conductivity-type regions disposed in the termination region, the first-conductivity-type doping concentration of the plurality of third first-conductivity-type regions being lower than the first-conductivity-type doping concentration of the plurality of second first-conductivity-type regions, and
the plurality of second-conductivity-type regions include:
a plurality of first second-conductivity-type regions disposed in the active region;
a plurality of second second-conductivity-type regions disposed in the transition region, the second-conductivity-type doping concentration of the plurality of second second-conductivity-type regions being lower than the second-conductivity-type doping concentration of the plurality of first second-conductivity-type regions; and
a plurality of third second-conductivity-type regions disposed in the termination region, the second-conductivity-type doping concentration of the plurality of third second-conductivity-type regions being lower than the second-conductivity-type doping concentration of the plurality of second second-conductivity-type regions.

4. The semiconductor device according to claim 1, wherein
a width of each of the plurality of first-conductivity-type regions is the same in the active region, the transition region, and the termination region,
a width of each of the plurality of second-conductivity-type regions is the same in the active region, the transition region, and the termination region, and
any one of the plurality of first-conductivity-type regions and one of the plurality of second-conductivity-type regions that is adjacent to said any one of the plurality of first-conductivity-type regions have balanced charge therebetween.
